(19) United States
(12) Patent Application Publication
(10) Pub. No.: US 2014/0266749 A1
(43) Pub. Date: Sep. 18, 2014

(54) PRINTED LIGHT-EMITTING DIODE CIRCUIT FOR ITEM VALIDATION

(71) Applicant: Lockheed Martin Corporation, Bethesda, MD (US)

(72) Inventors: Toby D. Thomas, Southlake, TX (US); Steven D. Roper, Mansfield, TX (US); Becky B. Wallace, Irving, TX (US); Joseph G. Metzger, Grapevine, TX (US)

(73) Assignee: Lockheed Martin Corporation, Bethesda, MD (US)

(21) Appl. No.: 14/010,968

(22) Filed: Aug. 27, 2013

Related U.S. Application Data
(60) Provisional application No. 61/794,180, filed on Mar. 15, 2013.

(51) Int. Cl. G09F 9/33; G01R 31/02; G06K 19/07; H05B 33/08

(52) U.S. Cl. CPC G09F 9/33; H05B 33/0842; G01R 31/02; G06K 19/0728
USPC 340/641; 315/362; 315/360; 340/815.45; 340/10.6

(57) ABSTRACT

Ink-printed electric circuits including light-emitting diodes (LEDs) for validation of items is disclosed. In one embodiment, the flexible circuit includes a pliant substrate, and an ink-printed electric circuit. The ink-printed electric circuit comprises at least one ink-printed LED printed on the pliant substrate. The ink-printed electric circuit is configured to couple to a power source, determine an open circuit condition, and cause the at least one LED to transition from a first state to a second state upon determining the open circuit condition.

### RELATED APPLICATION

This application claims the benefit of provisional patent application Ser. No. 61/794,180, “PRINTED LIGHT EMITTING DIODE CIRCUITRY TO ESTABLISH ENHANCED SECURITY AND MARKETING,” filed Mar. 15, 2013, the disclosure of which is hereby incorporated herein by reference in its entirety.

### TECHNICAL FIELD

The embodiments relate generally to ink-printed electric circuits, and in particular to ink-printed electric circuits with light-emitting diodes for use in validating items.

### BACKGROUND

The need or desire to validate an item arises in many contexts, including counterfeiting, security, authentication, and the like. Mechanisms for validating items can sometimes be cost-prohibitive for use with relatively low-cost items, or may be relatively easily foiled in some contexts.

The use of printed electric circuits is an area of growing interest. The ability to impart electric circuits onto various substrates provides substantial opportunity for relatively low-cost electric circuits and the use thereof in a variety of applications, including the validation of items.

### SUMMARY

The embodiments relate to ink-printed electric circuits with light-emitting diodes for validation of items. The embodiments provide relatively low-cost electric circuits useful in authenticating items, and reducing counterfeiting.

In one embodiment, a flexible circuit is provided. The flexible circuit includes a pliant substrate and an ink-printed electric circuit that comprises at least one ink-printed light-emitting diode (LED) printed on the pliant substrate. The ink-printed electric circuit is configured to couple to a power source, determine an open circuit condition, and cause the at least one LED to transition from a first state to a second state upon determining the open circuit condition. In one embodiment, the transition may be from an on state to an off state. In another embodiment, the transition may be from an off state to an on state. Among other uses, the flexible circuit may facilitate alerting an individual that a container, such as a bottle, has been opened.

In another embodiment, a labeling system is provided. The labeling system includes a label comprising a pliant substrate, and an ink-printed electric circuit that comprises a plurality of ink-printed LEDs printed on the pliant substrate. The ink-printed electric circuit is configured to couple to a power source, and initiate a lighting sequence of the plurality of ink-printed LEDs in a predetermined pattern. The labeling system may also include a device that comprises an optical sensor, and a processor that is coupled to the optical sensor and is configured to sense a lighting sequence of the plurality of ink-printed LEDs. The processor determines that the lighting sequence of the plurality of ink-printed LEDs was in the predetermined pattern, and indicates to a user that the lighting sequence of the plurality of ink-printed LEDs was in the predetermined pattern.

In another embodiment, another labeling system is provided. The labeling system includes a pliant substrate and an ink-printed electric circuit printed on the pliant substrate. The ink-printed electric circuit includes an ink-printed memory, at least one ink-printed LED, and an ink-printed radio-frequency identification (RFID) module configured to transmit and receive data. The ink-printed electric circuit is configured to couple to a power source, provide data to a validation device, receive a validation indication, and, based on the validation indication, cause the at least one ink-printed LED to emit light.

In another embodiment, an authentication system is provided. The authentication system includes a first pliant substrate configured to be attached to a first item. A first ink-printed electric circuit is printed on the first pliant substrate, and comprises a first conductive contact configured to couple to a second ink-printed electric circuit printed on a second pliant substrate. The first ink-printed electric circuit is configured to couple to a first power source, and communicate first authentication data to the second ink-printed electric circuit when coupled to the second ink-printed electric circuit via the conductive contact. The authentication system also includes a second pliant substrate that is configured to be attached to a second item, and includes a second conductive contact that is configured to couple to the first ink-printed electric circuit, and at least one ink-printed LED. The second ink-printed electric circuit is configured to couple to a second power source, receive the first authentication data from the first ink-printed electric circuit when coupled to the first ink-printed electric circuit, make an authentication determination based at least in part on the first authentication data, and based on the authentication determination, cause the at least one ink-printed LED to emit light.

In yet another embodiment, a flexible circuit is provided. The flexible circuit includes a pliant substrate, and an ink-printed electric circuit that includes at least one ink-printed LED printed on the pliant substrate. The ink-printed electric circuit is configured to couple to a power source, maintain track of a predetermined duration of time, and at the end of the predetermined duration of time, cause the at least one ink-printed LED to transition from a first state to a second state.

In yet another embodiment, a method for producing a flexible circuit is provided. The method includes receiving printing data identifying an electric circuit comprising at least one ink-printed LED. The electric circuit is configured to couple to a power source, determine an open circuit condition, and cause the at least one ink-printed LED to emit light upon determining the open circuit condition. The method includes printing the electric circuit using conductive ink on a pliant substrate.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWINGS

The accompanying drawing figures incorporated in and forming a part of this specification illustrate several aspects of the disclosure, and together with the description serve to explain the principles of the disclosure.

FIG. 1 is a block diagram of a flexible circuit according to one embodiment;

FIG. 2 illustrates a cross-section taken along line A-A of FIG. 1 according to one embodiment;

FIG. 3 illustrates a cross-section taken along the line A-A of FIG. 1 according to another embodiment;

FIG. 4 illustrates a cross-section taken along the line A-A of FIG. 1 according to another embodiment;

FIG. 5 illustrates a cross-section taken along line B-B according to the embodiment illustrated in FIG. 4;

FIG. 6 illustrates the use of the flexible circuit illustrated in FIG. 1 on an item according to one embodiment;

FIG. 7 is a block diagram of a system for producing a flexible circuit according to one embodiment;

FIG. 8 is a flowchart of a method for producing a flexible circuit according to one embodiment;

FIG. 9 is a block diagram of a labeling system according to one embodiment;

FIG. 10 is a block diagram of a radio-frequency identification labeling system according to one embodiment;

FIG. 11 is a block diagram illustrating an authentication labeling system according to one embodiment;

FIG. 12 illustrates another embodiment of the authentication labeling system illustrated in FIG. 11; and

FIG. 13 illustrates another embodiment of the authentication labeling system illustrated in FIG. 11.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

FIG. 1 is a block diagram of a flexible circuit 10 according to one embodiment. The flexible circuit 10 includes a pliant substrate 12. The pliant substrate 12 may comprise any pliant substrate including, for example, a paper substrate or a mylar substrate. The pliant substrate 12 has a width 14 and a height 16. In some embodiments, the width 14 is greater than the height 16. In certain embodiments, the width 14 may be greater than twice the height 16.

The pliant substrate 12 includes an ink-printed electric circuit 18 (hereinafter, electric circuit 18). The electric circuit 18 may be printed on the pliant substrate 12 using any appropriate electronic, or conductive, ink suitable for generating conductive paths and electronic components.

The electric circuit 18 includes control logic 20, which comprises an ink-printed electronic circuit suitable for implementing the logic and functionality of the electric circuit 18. The electric circuit 18 may include one or more conductive paths 22 and one or more ink-printed light-emitting diodes (LEDs) 24. The LEDs may comprise inorganic LEDs (ILEDs), organic LEDs (OLEDs), quantum dot LEDs (QLEDs), or the like. The electric circuit 18 may be coupled to a power source 26, which may comprise, for example, a button cell power source or an ink-printed battery power source.

The pliant substrate 12 includes a weakened linear portion 28 that extends across the width 14 and separates a first portion 30 of the pliant substrate 12 from a second portion 32 of the pliant substrate 12. The weakened linear portion 28 may comprise, for example, a score line, a die-cut line, a weakened separation line, or any other mechanism used to weaken relatively thin planar items such as paper or the like.

In one embodiment, the electric circuit 18 includes a main portion 34 and one or more extension portions 36. The extension portions 36 may comprise conductive paths.

In one embodiment, the electric circuit 18 is configured to couple to the power source 26, determine an open circuit condition, and cause at least one of the LEDs 24 to transition from a first state to a second state upon determining the open circuit condition. In particular, the electric circuit 18 may be configured to determine that the extension portion 36 has been separated from the main portion 34 of the electric circuit 18, such as might occur if the first portion 30 of the pliant substrate 12 is separated from the second portion 32 such as, for example, by tearing the first portion 30 along the weakened linear portion 28. Under such circumstances, the electric circuit 18 may cause the LEDs 24 to transition from an off state to an on state to alert a user to the open circuit condition. Alternatively, the electric circuit 18 may cause the LEDs 24 to transition from an on state to an off state to alert the user to such a condition.

In another embodiment, the electric circuit 18 may be configured to maintain track of a predetermined duration of time. At the end of the predetermined duration of time, the electric circuit 18 may cause one or more of the LEDs 24 to transition from a first state to a second state. For example, the LEDs 24 may transition from an off state to an on state, or from an on state to an off state. Such embodiment may provide a relatively inexpensive mechanism for validating the life of an item, such as a bottle of a liquid or other fungible good.

FIG. 2 is a cross-sectional view taken along line A-A of FIG. 1. In one embodiment, the pliant substrate 12 may be porous, facilitating the absorption to some extent of the conductive paths 22 on a face 38 of the pliant substrate 12.

FIG. 3 is a cross-sectional view taken along the line A-A of FIG. 1 according to another embodiment. In this embodiment, an adhesive layer 40 is applied to a first face 42 to cover the first face 42, and the electric circuit 18 is printed on a second face 44 of the pliant substrate 12.

FIG. 4 is a cross-sectional view taken along the line A-A of FIG. 1 according to another embodiment. In this embodiment, the electric circuit 18 is applied to the first face 42 of the pliant substrate 12, and the adhesive layer 40 is applied on top of the electric circuit 18. This embodiment may make tampering with the electric circuit 18 more difficult than embodiments wherein the electric circuit 18 is printed on an outer face of the pliant substrate 12.

FIG. 5 is a cross-sectional view taken along the line B-B of FIG. 1 according to one embodiment. As illustrated with respect to FIG. 4, the electric circuit 18 is first printed on the first face 42 of the pliant substrate 12, and the adhesive layer 40 is then applied to the first face 42 of the pliant substrate 12. In one embodiment, the pliant substrate 12 may be transparent, such that the LEDs 24, when in the on state, can be seen through the pliant substrate 12.

FIG. 6 illustrates a use of the flexible circuit 10 illustrated in FIG. 1 on an item 50 according to one embodiment. In this embodiment, the item 50 comprises a container, such as a bottle, that includes a cap 52. The cap 52 has a bottom rim 56. The pliant substrate 12 may be affixed about the item 50 circumferentially, such that the first portion 30 is adhered to the cap 52, and the second portion 32 is adhered to the neck portion 54. The pliant substrate 12 may be positioned such that the weakened linear portion 28 is positioned approximately on the bottom rim 56 of the cap 52. The electric circuit 18 may be configured such that the LEDs 24 continuously light or flash light so long as the extension portions 36 remain conductively coupled to the main portion 34 (FIG. 1) of the electric circuit 18.

If, for example, a user twists the cap 52 sufficiently such that the pliant substrate 12 tears along the weakened linear portion 28 and disconnects one of the extension portions 36 from the main portion 34 of the electric circuit 18, the electric circuit 18 may transition the LEDs 24 from an on state to an off state. Alternatively, the electric circuit 18 may be configured to transition the LEDs 24 from an off state to an on state upon detecting that the extension portions 36 are no longer conductively coupled to the main portion 34. Thus, the flexible circuit 10, in this embodiment, may be used to validate that a container that has been sealed has remained sealed. If an individual has tampered with the item 50 and removed the cap 52 from the neck portion 54, such tampering would be immediately evident based on the state of the LEDs 24. The relatively low cost of the flexible circuit 10 may make it feasible to use a flexible circuit 10 with items 50 that are used to contain even relatively low-cost goods, such as bottles of wine, champagne, and the like.

FIG. 7 is a block diagram of a system 60 suitable for creating a flexible circuit according to one embodiment. The system 60 includes a device 62, such as a desktop computer, laptop computer, computing tablet, or the like. The device 62 includes a processor 64 and a memory 66. The memory 66 may include software instructions that configure the processor 64 to provide certain functionality. The software instructions are represented by a circuit design module 68, which may comprise any suitable circuit design technology for designing electric circuits. The circuit design module 68 may be used by a circuit designer to lay out the desired ink-printed electric circuit, such as the electric circuit 18, illustrated in FIG. 1.

During the course of designing the electric circuit 18, the user may interact with the circuit design module 68 via a display 70. After the desired electric circuit 18 has been designed, the user may print the electric circuit 18 onto the pliant substrate 12 via a printer 72, which is coupled to the device 62 via a printer interface 74. The printer 72 inputs the pliant substrate 12 and outputs the pliant substrate 12 with the electric circuit 18 printed thereon, using ink that is conductive and suitable for generating electric circuits. The pliant substrate 12 may then be provided to an adhesive application function 76 that applies adhesive to a face of the pliant substrate 12. As discussed above with regard to FIG. 1, the adhesive may be applied to the face upon which the electric circuit 18 is printed or applied to the opposite face of the pliant substrate 12.

FIG. 8 is a flowchart of a method for producing a flexible circuit according to one embodiment, and will be discussed in conjunction with FIG. 7. The printer 72 receives data from the device 62 that identifies the electric circuit that includes an ink-printed LED (FIG. 8, Block 1000). The printer 72 then prints the electric circuit on the pliant substrate 12 using conductive ink (FIG. 8, Block 1002).

FIG. 9 is a block diagram of a labeling system 80 according to another embodiment. The labeling system 80 includes a pliant substrate 82 that may comprise, for example, any suitable pliant substrate that may be sufficiently flexible for application to an item. The pliant substrate 82 includes an ink-printed electric circuit 84 (hereinafter, electric circuit 84). The electric circuit 84 includes a plurality of ink-printed LEDs 86, and control logic 88. The electric circuit 84 is coupled to a power source 90, which may comprise, for example, a button cell or an ink-printed battery. In one embodiment, the control logic 88 is configured to initiate a light-emitting sequence of the plurality of ink-printed LEDs 86 in a predetermined pattern. The light-emitting sequence may be relatively rapid and may involve non-uniform lighting times of individual LEDs 86.

The pliant substrate 82 may be applied or otherwise affixed to an item 92. The item 92 may comprise, or may contain, an object for which it is desired to validate its authenticity. The labeling system 80 may also include a device 94 suitable for reading the light-emitting sequence in the predetermined pattern of the electric circuit 84. In one embodiment, the device 94 may include a processor 96 and a sensor 98 that is capable of detecting light of the frequencies emitted by the plurality of ink-printed LEDs 86. The device 94 may also include a memory 100 that includes predetermined pattern data 102 that identifies the predetermined pattern of the electric circuit 84. The device 94 may be held in sufficient proximity to the pliant substrate 82 such that the sensor 98 can sense the emission of the light of the plurality of ink-printed LEDs 86. The processor 96 may access the predetermined pattern data 102 and determine whether the electric circuit 84 is initiating the lighting sequence of the plurality of the ink-printed LEDs 86 in the predetermined pattern. If so, the processor 96 may indicate that the item 92 is authentic. Otherwise, the processor 96 may indicate on a display 104 that the item 92 is not authentic.

In one embodiment, the plurality of the ink-printed LEDs 86 may emit light in a particular band of the visible spectrum. In another embodiment, the plurality of ink-printed LEDs 86 may emit light in an infrared band of the infrared spectrum. Thus, the sensor 98 may be configured to sense light emitted in either the visible spectrum or the infrared spectrum.

In one embodiment, the electric circuit 84 may be configured to iteratively and on a continuous basis initiate the lighting sequence of the plurality of the ink-printed LEDs 86 in the predetermined pattern until the power source 90 is drained. The continuous lighting of the predetermined pattern may make copying the pliant substrate 82 for the purposes of counterfeiting impossible or extremely difficult.

FIG. 10 is a block diagram of a radio-frequency identification (RFID) labeling system 106 according to one embodiment. The RFID labeling system 106 includes a pliant substrate 108, which may comprise, for example, a paper substrate, a mylar substrate, or any other pliant substrate. The pliant substrate 108 has printed thereon an ink-printed electric circuit 110 (hereinafter “electric circuit 110”) that includes a plurality of ink-printed LEDs 112 and RFID control logic 114. The RFID control logic 114 may include an RFID module that is configured to transmit and receive data via radio frequency waves. The electric circuit 110 may be coupled to or may comprise a power source 116. The power source 116 may comprise, for example, a button cell battery or an ink-printed battery. The pliant substrate 108 may be affixed or otherwise attached to an item 118, which may comprise or may contain an object whose authenticity it is desired to validate.

The RFID labeling system 106 may also include a validation device 120. The validation device 120 includes a processor 122 coupled to an RFID module 124. A validation module 126 contained in a memory 128 may utilize the RFID module 124 to communicate with the RFID control logic 114 of the electric circuit 110. In response to a request from the validation module 126, the RFID control logic 114 may provide data to the validation device 120. The validation device 120 may then validate the data received from the RFID control logic 114. If the data is properly validated, the validation module 126 may, via the RFID module 124, indicate to the electric circuit 110 that the data has been properly validated. In response, the electric circuit 110 may then cause one or more of the plurality of the ink-printed LEDs 112 to emit light in a certain color and/or pattern, indicating proper validation. If the validation module 126 is not able to properly validate the data, the validation module 126, may, via the RFID module 124, indicate to the electric circuit 110 that the validation has failed, and the electric circuit 110 may cause the plurality of ink-printed LEDs 112 to emit light in a different color and/or pattern, indicating a validation failure. In one embodiment, the validation device 120 may include a display 130, upon which the validation result may be displayed.

In one embodiment, certain of the LEDs 112 may emit light in a certain wavelength, such as in a green wavelength, and are caused to emit light upon proper validation. Other LEDs 112 may be configured to emit light at a different wavelength, such as a red wavelength, and may be caused to emit light if the data is not properly validated. In yet other embodiments, the LEDs 112 may be arranged in a grid, such that one or more words can be displayed upon proper validation, or upon improper validation.

FIG. 11 is a block diagram of an authentication labeling system 132 according to one embodiment. In this embodiment, multiple pliant substrates may be used to validate that items that are supposed to be related to one another are in fact the intended and/or original related items. For example, in the context of legal documents, an agreement may comprise a first sheet of paper 133A and a second sheet of paper 133B. In one embodiment, a first pliant substrate 134 may be affixed to the first sheet of paper 133A. The first pliant substrate 134 includes an ink-printed electric circuit 136 (hereinafter “electric circuit 136”). The electric circuit 136 includes one or more ink-printed LEDs 138, and control logic 140. The electric circuit 136 may be coupled to a power source 142, which may comprise, for example, a button cell or an ink-printed battery. The electric circuit 136 may also include a first conductive contact 144, which may comprise for example, one or more enlarged ink-printed contact areas. A second pliant substrate 146 may be affixed to the second sheet of paper 133B. The second pliant substrate 146 includes an ink-printed electric circuit 148 (hereinafter “electric circuit 148”) that includes control logic 150. The electric circuit 148 may be coupled to a power source 152. The electric circuit 148 may also include a second conductive contact 154. In operation, a user may orient the second sheet of paper 133B such that the second conductive contact 154 is in conductive contact with the first conductive contact 144. When the electric circuit 136 is conductively coupled to the electric circuit 148, the control logic 140 may communicate to the control logic 150 to make a determination as to whether the electric circuit 136 is properly paired with a valid electric circuit 148. For example, the control logic 140 may provide certain authentication data to the control logic 150. Upon determining an authentication determination based on authentication data communicated between the control logic 140 and the control logic 150, the electric circuit 136 may cause the one or more ink-printed LEDs 138 to emit light, indicating authentication or a failure to authenticate. In one embodiment, the one or more ink-printed LEDs 138 may emit light in the visible spectrum. In another embodiment, the one or more ink-printed LEDs 138 may emit light in an infrared band of the infrared spectrum.

FIG. 12 is a block diagram illustrating another embodiment of the authentication labeling system 132. In this embodiment, the second pliant substrate 146 may be affixed to the underside of the second sheet of paper 133B to simplify the coupling of the first conductive contact 144 with the second conductive contact 154.

FIG. 13 illustrates the authentication labeling system 132 according to another embodiment. In this embodiment, a second pliant substrate 146A includes foldable second conductive contacts 154A. The foldable second conductive contacts 154A may be pressed against the first conductive contact 144 without having to manipulate the second sheet of paper 133B, other than to place the second sheet of paper 133B in close proximity to the first sheet of paper 133A.

Although the embodiments have been discussed in the context of the validation of items, the embodiments are not so limited, and have wide applicability in other areas, including, for example, to entice or otherwise attract the attention of potential purchasers of products. In such embodiments, products, or packages containing products, may bear a labeling system that includes an ink-printed electric circuit that comprises a plurality of ink-printed LEDs. The ink-printed electric circuit may be printed on a pliant substrate, and be configured to couple to a power source, and initiate a lighting sequence of the plurality of ink-printed LEDs in a predetermined pattern to gain the attention of a potential purchaser of the product. In some embodiments, the system may also include a proximity sensor and a processor that is coupled to the proximity sensor to trigger, or alternately configure, the lighting sequence of the ink-printed LEDs when a person is determined to be in proximity of the product, such that the label does not light until the presence of a human is detected, or the lighting sequence is changed upon the detection of the presence of the human.

Those skilled in the art will recognize improvements and modifications to the preferred embodiments of the present disclosure. All such improvements and modifications are considered within the scope of the concepts disclosed herein and the claims that follow.

What is claimed is:

1. A flexible circuit, comprising:
a pliant substrate; and
an ink-printed electric circuit comprising at least one ink-printed light-emitting diode (LED) printed on the pliant substrate, the ink-printed electric circuit configured to:
couple to a power source;
determine an open circuit condition; and
cause the at least one LED to transition from a first state to a second state upon determining the open circuit condition.

2. The flexible circuit of claim 1, wherein the first state is an on state and the second state is an off state.

3. The flexible circuit of claim 1, wherein the first state is an off state and the second state is an on state.

4. The flexible circuit of claim 1, wherein the pliant substrate comprises one of a paper substrate and a mylar substrate.

5. The flexible circuit of claim 1, wherein the pliant substrate further comprises an adhesive layer covering a first face of the pliant substrate.

6. The flexible circuit of claim 5, wherein the ink-printed electric circuit is printed on the first face of the pliant substrate.

7. The flexible circuit of claim 1, further comprising:
the power source; and
wherein the power source comprises a button cell.

8. The flexible circuit of claim 1, further comprising:
the power source; and
wherein the power source comprises an ink-printed battery.

9. The flexible circuit of claim 1, wherein the at least one ink-printed LED comprises a plurality of ink-printed LEDs.

10. The flexible circuit of claim 1, wherein the pliant substrate is porous and absorbs at least a portion of the ink-printed electric circuit.

11. The flexible circuit of claim 1, wherein the pliant substrate has a width and a height, the width being greater than the height, the pliant substrate comprising a weakened linear portion extending across the width, the weakened linear portion separating a first portion of the pliant substrate from a second portion of the pliant substrate, and the electric circuit comprising a main portion and an extension portion, the extension portion being located on the first portion of the pliant substrate and the extension portion extending from the main portion across the weakened linear portion into the second portion of the pliant substrate.

12. A labeling system, comprising:
a label comprising:
a pliant substrate; and
an ink-printed electric circuit comprising a plurality of ink-printed light-emitting diodes (LEDs) printed on the pliant substrate, the ink-printed electric circuit configured to:
couple to a power source; and
initiate a lighting sequence of the plurality of ink-printed LEDs in a predetermined pattern.

13. The labeling system of claim 12, further comprising:
a device comprising:
an optical sensor;
a processor coupled to the optical sensor and configured to:
sense a lighting sequence of the plurality of ink-printed LEDs;
determine that the lighting sequence of the plurality of ink-printed LEDs was in the predetermined pattern; and
indicate to a user that the lighting sequence of the plurality of ink-printed LEDs was in the predetermined pattern.

14. The labeling system of claim 12, wherein the plurality of ink-printed LEDs emits light in a visible spectrum.

15. The labeling system of claim 12, wherein the plurality of ink-printed LEDs emits light in an infrared spectrum.

16. The labeling system of claim 15, wherein the optical sensor is configured to sense light emitted in the infrared spectrum.

17. The labeling system of claim 12, wherein the processor is further configured to iteratively on a continuous basis initiate the lighting sequence of the plurality of ink-printed LEDs in the predetermined pattern until the power source is drained.

18. A labeling system, comprising:
a pliant substrate; and
an ink-printed electric circuit printed on the pliant substrate, comprising:
an ink-printed memory;
at least one ink-printed light emitting diode (LED); and
an ink-printed radio-frequency identification (RFID) module configured to transmit and receive data;
the ink-printed electric circuit configured to:
couple to a power source; and
provide, via the RFID module, data to a validation device;
receive, via the RFID module, a validation indication; and
based on the validation indication, cause the at least one ink-printed LED to emit light.

19. The labeling system of claim 18, further comprising a plurality of ink-printed LEDs, including the at least one ink-printed LED, and wherein the ink-printed electric circuit is configured to, based on the validation indication, cause the plurality of ink-printed LEDs to emit light in a predetermined pattern.

20. The labeling system of claim 19, wherein the predetermined pattern forms a word that indicates whether the validation indication indicates validation or improper validation.

21. The labeling system of claim 18, further comprising:
the validation device, wherein the validation device is configured to:
receive the data from the RFID module;
make a determination whether the data is valid; and
based on the determination, send the RFID module the validation indication.

22. An authentication system, comprising:
a first pliant substrate configured to be attached to a first item;
a first ink-printed electric circuit printed on the first pliant substrate, the first ink-printed electric circuit comprising a first conductive contact configured to couple to a second ink-printed electric circuit printed on a second pliant substrate, the first ink-printed electric circuit configured to:
couple to a first power source; and
communicate first authentication data to the second ink-printed electric circuit when coupled to the second ink-printed electric circuit via the first conductive contact;
the second pliant substrate, the second pliant substrate configured to be attached to a second item;
the second ink-printed electric circuit comprising:
a second conductive contact configured to couple to the first ink-printed electric circuit, and at least one ink-printed light-emitting diode (LED);
the second ink-printed electric circuit configured to:
couple to a second power source;
receive the first authentication data from the first ink-printed electric circuit when coupled to the first ink-printed electric circuit;
make an authentication determination based at least in part on the first authentication data; and
based on the authentication determination, cause the at least one ink-printed LED to emit light.

23. The authentication system of claim 22, wherein the at least one ink-printed LED comprises a first ink-printed LED that emits visible light in a first light band, and a second ink-printed LED that emits visible light in a second light band, wherein if the authentication determination indicates that the first item is authentic, the second ink-printed electric circuit is configured to cause the first ink-printed LED to emit the visible light in the first light band, and if the authentication determination indicates that the first item is non-authentic, the second ink-printed electric circuit is configured to cause the second ink-printed LED to emit the visible light in the second light band.

24. A flexible circuit, comprising:
a pliant substrate; and
an ink-printed electric circuit comprising at least one ink-printed light-emitting diode (LED) printed on the pliant substrate, the ink-printed electric circuit configured to:
couple to a power source;
maintain track of a predetermined duration of time; and
at the end of the predetermined duration of time, cause the at least one ink-printed LED to transition from a first state to a second state.

25. The flexible circuit of claim 24, wherein the first state is an on state and the second state is an off state.

26. The flexible circuit of claim 24, wherein the first state is an off state and the second state is an on state.

27. A method for producing a flexible circuit, comprising:
receiving printing data identifying an electric circuit comprising at least one ink-printed light-emitting diode (LED), the electric circuit configured to:
couple to a power source;
determine an open circuit condition;
cause the at least one LED to emit light upon determining the open circuit condition; and
printing the electric circuit using conductive ink on a pliant substrate.

28. The method of claim 27, wherein the printing data identifies the power source, and further comprising printing the power source.
